(19) United States
(12) Patent Application Publication
(10) Pub. No.: US 2025/0383483 A1
(43) Pub. Date: Dec. 18, 2025

(54) DISPLAY SCREEN COVER PLATE, DISPLAY MODULE AND DISPLAY DEVICE

(71) Applicant: Xiamen Tianma Display Technology Co., Ltd., Xiamen (CN)

(72) Inventors: Jun HUANG, Xiamen (CN); Jinjin YANG, Xiamen (CN); Zhiwei WANG, Xiamen (CN)

(73) Assignee: Xiamen Tianma Display Technology Co., Ltd., Xiamen (CN)

(21) Appl. No.: 18/888,190

(22) Filed: Sep. 18, 2024

(30) Foreign Application Priority Data
Jun. 14, 2024 (CN) 202410772252.X

(51) Int. Cl. G02B 5/00

(52) U.S. Cl. CPC G02B 5/003

(57) ABSTRACT

The present application relates to a display screen cover plate, a display module and a display device, in which the display screen cover plate includes a substrate and a light shielding layer, the substrate includes a visible area and a border area, where the border area is arranged around the visible area; and the light shielding layer is arranged on one side of the substrate and located in the border area, at least part of a surface of one side of the light shielding layer facing away from the substrate is a concave-convex surface, and an orthographic projection of the concave-convex surface on the substrate covers at least part of the border area. The embodiments of the present application provide a display screen cover plate, a display module and a display device.

### CROSS-REFERENCE TO RELATED APPLICATIONS

This application claims priority to Chinese Patent Application No. 202410772252.X, titled “DISPLAY SCREEN COVER PLATE, DISPLAY MODULE AND DISPLAY DEVICE” and filed on Jun. 14, 2024, which is hereby incorporated by reference in its entirety.

### TECHNICAL FIELD

The present application relates to the field of display technology, and in particular to a display screen cover plate, a display module and a display device.

### BACKGROUND

With the continuous development of display technology, folding screen technology continues to mature and is gradually applied in users' daily lives.

During the bending process of the folding screen, stretch bubbles may be generated between the optical glue at the edge and the object to be bonded. At present, the industry's demand for the number of bends is getting higher and higher, and the stretch bubbles may also increase accordingly. In addition, the folding border will be further narrowed in the future, and the risk will also increase accordingly.

After multiple bends form stretch bubbles, the stretch bubbles may cause bending or penetration shedding between the film layers. At the same time, the bubbles may gradually extend to the display area, thereby causing adverse effects on the display. Therefore, how to alleviate the extension of bubbles is an urgent problem to be solved in this field.

### SUMMARY

The embodiments of the present application provide a display screen cover plate, a display module and a display device.

In the first aspect, according to the embodiments of the present application, there is provided a display screen cover plate, which includes: a substrate comprising a visible area and a border area, where the border area is arranged around the visible area; and a light shielding layer arranged on one side of the substrate and located in the border area, where at least part of a surface of one side of the light shielding layer facing away from the substrate is a concave-convex surface, and an orthographic projection of the concave-convex surface on the substrate covers at least part of the border area.

In the second aspect, according to the embodiments of the present application, there is provided a display module, which includes: the display screen cover plate and the display panel described above, the display panel and the light shielding layer are located on the same side of the substrate, where the display panel includes a display area and a peripheral area, at least part of the peripheral area surrounds the display area corresponding to a visible area in a thickness direction of the display panel, the peripheral area corresponding to a border area in the thickness direction, and the display area of the display panel emitting light through the visible area.

In the third aspect, according to the embodiments of the present application, there is provided a display device, including the display module as described above.

### BRIEF DESCRIPTION OF THE DRAWINGS

The features, advantages and technical effects of the exemplary embodiments in the present application will be described below with reference to the drawings.

FIG. 1 is a schematic plan view of an array substrate according to an embodiment of the present application;

FIG. 2 is a schematic plan view of another array substrate according to an embodiment of the present application;

FIG. 3 is a schematic cross-sectional view at N-N in FIG. 1;

FIG. 4 is a partial enlarged view of A in FIG. 3;

FIG. 5 is a schematic plan view of a first pattern according to an embodiment of the present application;

FIG. 6 is a schematic plan view of another first pattern according to an embodiment of the present application;

FIG. 7 is a schematic plan view of another first pattern according to an embodiment of the present application;

FIG. 8 is a schematic plan view of another first pattern according to an embodiment of the present application;

FIG. 9 is a schematic plan view of another first pattern according to an embodiment of the present application;

FIG. 10 is a schematic plan view of another first pattern according to an embodiment of the present application; and

FIG. 11 is a schematic structural diagram of a display module according to an embodiment of the present application.

### REFERENCE NUMERALS

100—display screen cover plate; 10—substrate; 20—light shielding layer; 21—concave-convex surface; AA—visible area; NA—border area; M—bending area; S—bending line;
30—first pattern; 31—opening portion; 32—sub-pattern; 33—sub-opening;
34—first extension portion; 35—second extension portion; 36—third extension portion; 40—optical adhesive layer;
200—display panel; 1—bubbles.

In the drawings, the same reference numerals are used for the same components. The drawings are not drawn to actual scale.

### DETAILED DESCRIPTION

The features and exemplary embodiments of various aspects in the present application are described in detail below. In the following detailed description, many specific details are proposed to provide a comprehensive understanding of the present application. However, it is obvious to those skilled in the art that the present application can be implemented without some of these specific details. The following description of the embodiments is only intended to provide a better understanding of the present application by illustrating examples of the present application. In the drawings and the following description, at least some of the known structures and technologies are not shown to avoid unnecessary ambiguity of the present application; and, for clarity, the size of some structures may be exaggerated. In addition, the features, structures or characteristics described below may be combined in one or more embodiments in any suitable manner.

The directional words appearing in the following description are all directions shown in the drawings, and do not limit the specific structures of the display screen cover plate, display module and display device in the present application. In the description of the present application, it is also necessary to explain that, unless otherwise clearly specified and limited, the terms “installation” and “connection” should be understood in a broad sense, for example, may be a fixed connection, a detachable connection, or an integral connection; directly connected or indirectly connected. For those in this field, the specific meanings of the above terms in the present application can be understood according to the specific circumstances.

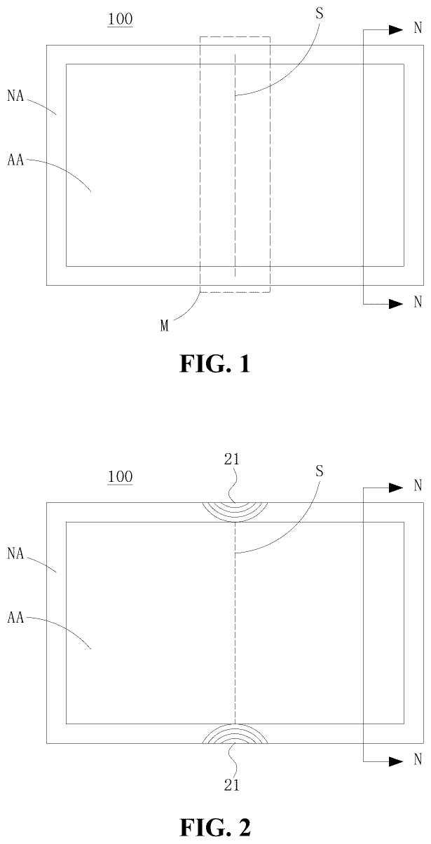

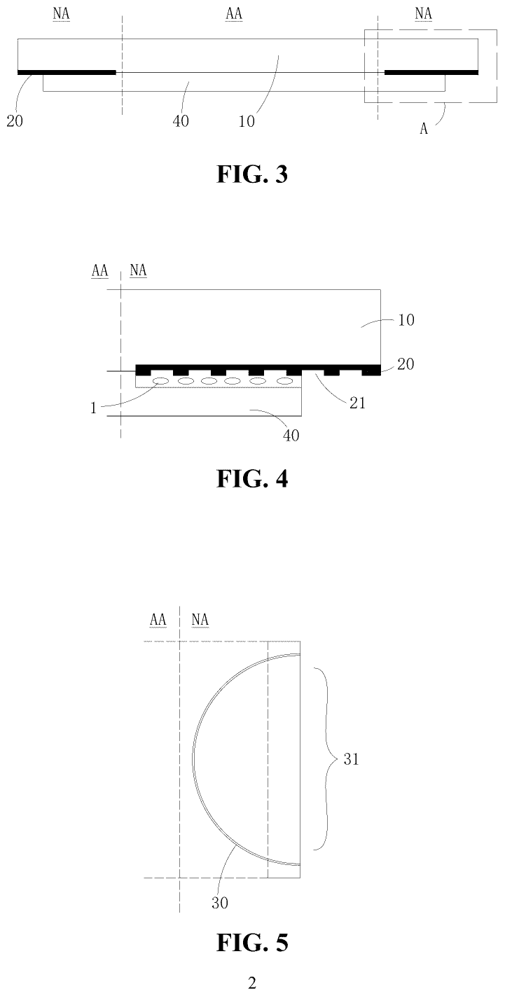

In order to better understand the present application, the display screen cover plate, display module and display device in the embodiments of the present application are described in detail below in conjunction with FIG. 1 to FIG. 11.

Referring to FIGS. 1 to 4, according to an embodiment of the present application, there is provided a display screen cover plate 100, which includes a substrate 10 and a light shielding layer 20, the substrate 10 including a visible area AA and a border area NA arranged around the visible area AA; the light shielding layer 20 being arranged on one side of the substrate 10 and located in the border area NA, in which at least part of a surface of one side of the light shielding layer 20 facing away from the substrate 10 is a concave-convex surface 21, and an orthographic projection of the concave-convex surface 21 on the substrate 10 covers at least part of the border area NA.

Optionally, the display screen cover plate 100 in this embodiment may be a bendable cover plate, herein the substrate 10 may be made of a flexible material, so that the bendability of the cover plate can be achieved.

Referring to FIG. 1 and FIG. 11, herein the substrate 10 has a visible area AA and a border area NA. The visible area AA can correspond to a sub-pixel position of the display panel 200, thereby realizing the display in the visible area AA. The border area NA corresponds to a non-display area of the display panel 200. Optionally, the border area NA can be arranged around the visible area AA and serve as an edge of the visible area AA. The present application does not specifically limit the relative position relationship between the border area NA and the visible area AA.

Since the border area NA does not have a display function, a light shielding layer 20 is required to be arranged at the border area NA. The light shielding layer 20 has a light absorbing effect, thereby absorbing the light in the external environment and the light at a large viewing angle of the visible area AA to prevent excess light from causing adverse effects on normal display. Optionally, the light shielding layer 20 may be a black ink layer.

The substrate 10 and the light shielding layer 20 are usually connected to the display panel 200 by using an optical adhesive layer 40, so that the display screen cover plate 100 is covered on the display panel 200. Optionally, the optical adhesive layer 40 may be made of materials such as OCA or OCR. After the optical adhesive layer 40 is used to form an adhesive connection with the display panel 200, it also has a light-transmitting effect to ensure the normal emission of light at the visible area AA.

This application mainly takes into account that when the display screen cover plate 100 is bent multiple times, bubbles 1 may be formed at the bends in the optical adhesive layer 40. After continuing to bend multiple times, the bubbles 1 may gradually extend and expand, and eventually easily cause the penetration shedding of optical adhesive layer 40, causing the separation failure between the film layers. At the same time, the bubbles 1 may also gradually extend to the visible area AA of the substrate 10, blocking the normal display of the screen, thereby causing display abnormalities and other undesirable phenomena.

Based on the above-mentioned considerations, in this embodiment, a concave-convex surface 21 is provided at the bottom of the light shielding layer 20, that is, the bottom surface of the light shielding layer 20 is provided as a concave-convex surface 21, and the concave-convex surface 21 is connected to the optical adhesive layer 40, so that the contact area between the two is increased, and the connection stability between the two is improved.

At the same time, when the bending bubbles 1 gradually appear in the optical adhesive layer 40, the bubbles 1 may be confined in the concave-convex surface 21. The concave-convex surface 21 is a retaining wall structure for the bubbles 1. The concave-convex surface 21 can form a certain barrier to the extension and diffusion of the bubbles 1, and decompose the transverse tensile stress generated on the optical adhesive layer 40 during bending into transverse and longitudinal reaction forces to weaken the deformation and extension of the optical adhesive layer 40, and finally alleviate the extension and diffusion of the bubbles 1, reduce the adverse effects of the bubbles 1 on the film-layer connection strength and display effect, and improve the overall bending yield.

Optionally, the concave-convex surface 21 can be understood as an uneven surface, which may be a regular pattern surface or an irregular pattern surface. The present application does not specifically limit the specific structure and molding process of the concave-convex surface 21, and can increase the contact area with the optical adhesive layer 40 and form a blocking effect on the stretchable bubbles 1 therein.

Optionally, since the light shielding layer 20 is located in the border area NA of the substrate 10, the concave-convex surface 21 on the light shielding layer 20 may be located at any position of the border area NA. The present application does not specifically limit the specific position of the concave-convex surface 21. It is usually necessary to arrange the concave-convex surface 21 at the corresponding light shielding layer 20 where the bending bubbles 1 are easily generated in the optical adhesive layer 40, so as to form a timely blocking effect on the bubbles 1 in the optical adhesive layer 40.

The embodiments of the present application provide a display screen cover plate 100. A light shielding layer 20 is provided at the border area NA of a substrate 10 so that the bottom of the light shielding layer 20 is provided with a concave-convex surface 21. When the bottom of the light shielding layer 20 is bonded with an optical adhesive layer 40, even after multiple bending, bubbles 1 in the optical adhesive layer 40 may be blocked by the concave-convex surface 21 of the light-shielding layer 20 to alleviate the extension of the bubbles 1, thereby reducing the risk of shedding between film layers due to the extension of the bubbles 1, improving the overall reliability of the display module, and preventing the module failure problem caused by shedding between structures. Simultaneously, the concave-convex surface 21 of the light shielding layer 20 can also prevent bubbles 1 from extending into the visible area AA, effectively limiting the bubbles 1 to the border area NA, avoiding the blocking effect of bubbles 1 on normal display, providing reliable guarantee for high-quality display, and ultimately improving the product yield with a more reliable display effect.

As an optional embodiment, referring to FIGS. 1 to 4. The display screen cover plate 100 includes a bending area M and a bending line S located in the bending area M. The display screen cover plate 100 may be bent with the bending line S as an axis, and an end portion of the bending line S is located within an orthographic projection of the concave-convex surface 21 on the substrate 10.

Optionally, the display screen cover plate 100 in this embodiment has a bending performance, and it itself has a bending area M and a bending line S. The display screen cover plate 100 may be folded in half through the bending line S to achieve a bending function.

Since the two end portions of the bending line S are located at the light shielding layer 20 of the border area NA, in order to prevent the bubbles 1 generated at the bending line S from extending to the visible area AA, in this embodiment, the concave-convex surface 21 of the light shielding layer 20 is arranged at the end portion position of the bending line S, therefore, after the bubbles 1 are generated by multiple bends, the concave-convex surface 21 can block the bubbles 1 in time to prevent the bubbles 1 from further extending and diffusing.

The embodiment of the present application provides a display screen cover plate 100, by arranging a concave-convex surface 21 at the end portion position of the bending line S, the concave-convex surface 21 can limit the bubbles 1 generated at the bending line S, and more specifically limit the extension of the bubbles 1, thereby having a better limiting effect and providing reliable protection for the entire module.

As an optional embodiment, referring to FIG. 2, the orthographic projection of the concave-convex surface 21 on the substrate 10 is symmetrically distributed with the bending line S as an axis.

The embodiment of the present application provides a display screen cover plate 100, the concave-convex surface 21 is arranged as an axisymmetric structure relative to the bending line S, so that the concave-convex surface 21 can be more fully formed on both sides of the bending line S, the bubbles 1 on both sides of the bending line S can be blocked at the same time, the blocking range of the concave-convex surface 21 on the extended bubbles 1 is increased, and the blocking ability of the bubbles 1 is further improved.

As an optional embodiment, referring to FIGS. 5 to 10. The concave-convex surface 21 includes a first pattern 30. An orthographic projection of the first pattern 30 in the thickness direction of the substrate 10 protrudes and extends toward the visible area AA. The first pattern 30 has an opening portion 31 formed by enclosing. An orthographic projection of the opening portion 31 in the thickness direction is arranged away from an opening of the visible area AA.

The concave-convex surface 21 in this embodiment has a first pattern 30. The first pattern 30 has a tendency to extend toward the visible area AA. This is mainly because the bubbles 1 may gradually move toward the visible area AA during the extension process. In order to correspond to the extension law of the bubbles 1, the first pattern 30 can be arranged toward the visible area AA, that is, the opening portion 31 of the first pattern 30 is arranged away from the visible area AA, so that the bubbles 1 can be captured in a larger range.

The embodiment of the present application provides a display screen cover plate 100, the first pattern 30 is protruded and extended toward the visible area AA, so that the first pattern 30 is more in line with the law of extension and diffusion of the bubbles 1, and it is easier to block and capture the bubbles 1 when approaching the visible area AA. The arrangement of the opening portion 31 makes the first pattern 30 have a larger blocking range, improving the blocking effect of the bubbles 1.

As an optional embodiment, the first pattern 30 includes a groove and/or a protrusion, and the groove and/or the protrusion being integrally formed with the light shielding layer 20.

Optionally, since the bottom surface of the light shielding layer 20 is arranged as a concave-convex surface 21, the concave-convex surface 21 can be formed by arranging a groove and/or a protrusion structure on the light shielding layer 20.

The groove and the protrusion structure are complementary to each other. When a groove is arranged on the bottom surface of the light shielding layer 20, corresponding protrusions may be formed on both sides of the groove, and vice versa. In this embodiment, concave-convex surface 21 structure of the light shielding layer 20 can be obtained by arranging at least one of the groove and the protrusion.

Optionally, when the light shielding layer 20 is black ink, after the light shielding layer 20 is coated on the bottom surface of the substrate 10 and cured, several grooves can be formed by etching, so as to simultaneously obtain the protrusion structure between the grooves to form the concave-convex surface 21. At this time, the light shielding layer 20 and the protrusion are in an integrated structure.

Of course, a micro-bump structure can also be connected and arranged on the flat bottom surface of the light shielding layer 20 to form a protrusion, so that a groove is synchronously formed between adjacent protrusions, and finally the concave-convex surface 21 of the light shielding layer 20 can be obtained. The specific molding process of the concave-convex surface 21 is not particularly limited in this application.

The embodiment of the present application provides a display screen cover plate 100, the grooves and/or protrusions are integrally molded with the light shielding layer 20 to obtain the concave-convex surface 21 structure, which improves the structural stability at the position of the concave-convex surface 21, is conductive to the process molding at the same time, reduces the process difficulty, and achieves higher molding efficiency.

As an optional embodiment, referring to FIGS. 5 to 10, the first pattern 30 includes a plurality of sub-patterns 32, each sub-pattern 32 encloses to form a sub-opening 33, an orthographic projection of the sub-opening 33 in the thickness direction is arranged away from the opening of visual area AA, and the plurality of sub-openings 33 together form an opening portion 31.

Optionally, in this embodiment, the first pattern 30 is arranged to a plurality of sub-patterns 32, each of which may be the same or different. Each sub-pattern 32 is actually the above-mentioned groove and/or protrusion structure, and a corresponding sub-opening 33 is provided. Each sub-opening 33 has a certain capacity for accommodating the bubbles 1. The plurality of sub-patterns 32 can form layers of blocking for the bendable bubbles 1. The sub-pattern 32 may be a variety of graphic structures. The present application does not specifically limit the first pattern 30 and sub-patterns 32 thereof.

Since the first pattern 30 can protrude and extend toward the visible area AA, each of the sub-patterns 32 therein can also protrude and extend toward the visible area AA, so that each sub-pattern 32 satisfies the extension characteristics of the bubbles 1, and each place blocks the bubbles 1 in layers in a larger range. The present application does not specifically limit the number of sub-patterns 32 in the first pattern 30, and can be set according to the actual range of the border area NA.

The embodiment of the present application provides a display screen cover plate 100, a plurality of sub-patterns 32 are arranged in the first pattern 30, so that the plurality of sub-patterns 32 in the first pattern 30 jointly restrict the generated bubbles 1, and the plurality of grooves and/or protrusion structures cause layers of obstruction to the movement of the bubbles 1, thereby improving the ability to restrict the bubbles 1, and thus effectively reducing the overall impact of the bubbles 1 on the display module.

As an optional embodiment, at least part of the sub-openings 33 formed by adjacent sub-patterns 32 overlap.

Optionally, the overlap between the sub-openings 33 of adjacent sub-patterns 32 may be completely overlapped or partially overlapped. The present application does not specifically limit the overlap area between the sub-openings 33. The overlap between the sub-openings 33 may cause the bubbles 1 to oscillate repeatedly therein, and the extension of the bubbles 1 is obstructed by the sub-patterns 32 in multiple directions, so that the bubbles 1 are better restricted between the sub-openings 33.

The embodiment of the present application provides a display screen cover plate 100, the sub-openings 33 of multiple sub-patterns 32 in the first pattern 30 are at least partially overlapped, thereby improving the overall complexity of the first pattern 30, forming a more sufficient restriction on the bubbles 1, improving the blocking force on the bubbles 1, and greatly reducing the impact of the bubbles 1 on the module.

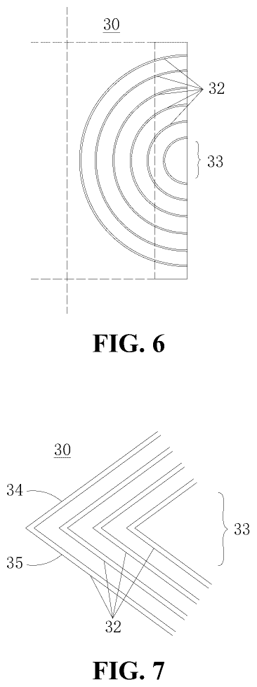

As an optional embodiment, referring to FIGS. 6 to 8. In a direction from the border area NA to the visible area AA, multiple sub-patterns 32 are spaced apart from each other and the sizes gradually increase. In any two adjacent sub-patterns 32, the sub-opening 33 of the sub-pattern 32 close to one side of the visible area AA covers the sub-opening 33 of the other sub-pattern 32.

Considering the blocking ability of the bubbles 1, the sub-pattern 32 arranged at a position close to the visible area AA in this embodiment is larger than the sub-pattern 32 close to the border area NA, so that the first pattern 30 has a better bubbles 1 blocking range near the visible area AA, preventing the bubbles 1 from extending into the visible area AA.

In a direction from the border area NA to the visible area AA, the sizes of the multiple sub-patterns 32 gradually increase, and the larger sub-openings 33 cover the smaller sub-openings 33, so that the first pattern 30 forms a layer-by-layer covered structure. When the bubbles 1 are generated at the bending line S, even if the bubbles 1 gradually extend toward the visible area AA, the multiple sub-patterns 32 arranged in layers can form a gradually increasing blocking range for the bubbles 1, thereby better restricting the bubbles 1 in the sub-opening 33.

The embodiment of the present application provides a display screen cover plate 100, multiple sub-patterns 32 are arranged as blocking structures with gradually increasing sizes, thereby increasing the blocking range of the first pattern 30 gradually, satisfying the extension law of the bubbles 1, improving the ability to intercept the bubbles 1 near the visible area AA, and blocking the bubbles 1 more effectively in the border area NA outside the visible area AA.

As an optional embodiment, referring to FIG. 6, the sub-pattern 32 includes an arc-shaped structure, and the sub-opening 33 is a semicircular structure. In a direction from the border area NA to the visible area AA, the radial dimensions of the multiple sub-patterns 32 gradually increase.

The embodiment of the present application provides a display screen cover plate 100. The sub-pattern 32 is arranged as an arc-shaped structure, so that the sub-pattern 32 has a larger blocking range, better restricts the movement of the bubbles 1, and the arc-shaped structure can better buffer the bending stress, reduce the risk of generating bubbles 1, and has better safety performance.

As an optional embodiment, referring to FIG. 7, the sub-pattern 32 includes a first extension portion 34 and a second extension portion 35 arranged intersectingly, the first extension portion 34 extending along a first direction and the second extension portion 35 extending along a second direction, the first extension portion 34 and the second extension portion 35 enclosing to form a sub-opening 33, and in the direction from the border area NA to the visible area AA, lengths of the first extension portions 34 and the second extension portions 35 of the multiple sub-patterns 32 gradually increase.

Optionally, in this embodiment, the sub-pattern 32 may also be arranged as a structural form in which the first extension portion 34 and the second extension portion 35 intersect, herein an acute angle can be formed between the first direction and the second direction, so that an acute angle structure is formed between the first extension portion 34 and the second extension portion 35, which can restrict the bubbles 1 in an opening of the acute angle. Of course, according to actual design requirements, the angle between the first extension portion 34 and the second extension portion 35 can be set to a right angle or an obtuse angle, which is not limited in this application, and it is sufficient as long as two extension portions can be formed to block the bubbles 1.

At this time, multiple sub-patterns 32 can also form a layer-by-layer surrounding structure. The sub-pattern 32 on the side close to the visible area AA has a larger length dimension than the sub-pattern 32 on the side close to the border area NA, so that the smaller sub-pattern 32 can be covered, and the blocking range of the first pattern 30 on the bubbles 1 may gradually increase, so that the bubbles 1 can be better restricted in the sub-opening 33 with a gradually expanding opening.

Optionally, the first extension portion 34 and the second extension portion 35 may be in a groove structure or a protrusion structure, and the bottom surface of the light shielding layer 20 may be a concave-convex surface 21. The first extension portion 34 and the second extension portion 35 may be obtained by different process moldings, which is not limited in the present application.

The embodiment of the present application provides a display screen cover plate 100, which provides another shape of the first pattern 30 by arranging the sub-pattern 32 as a structural form in which the first extension portion 34 and the second extension portion 35 intersect, and the sub-opening 33 formed by enclosing the two is used to limit the movement of the bubbles 1, which can also improve the blocking ability of the bubbles 1, and the structure is simple and regular, and is convenient for process molding.

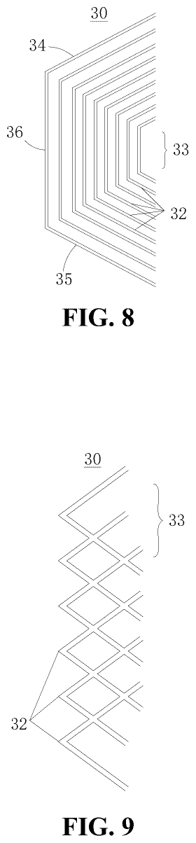

As an optional embodiment, referring to FIG. 8, the sub-pattern 32 includes a third extension portion 36 connected between the first extension portion 34 and the second extension portion 35, and the third extension portion 36 extends along a third direction, and the third direction intersects with the first direction and the second direction in pairs, and the first extension portion 34, the second extension portion 35 and the third extension portion 36 are enclosed together to form a sub-opening 33.

In this embodiment, on the basis of the first extension portion 34 and the second extension portion 35, a third extension portion 36 is further added, herein the third extension portion 36 is located between the first extension portion 34 and the second extension portion 35 and intersects with the two. As shown in the figure, the third extension portion 36 and the first extension portion 34 may be at an obtuse angle, and the third extension portion 36 and the second extension portion 35 may also be at an obtuse angle. The present application does not specifically limit the specific angle range.

By analogy, the sub-pattern 32 may be arranged as a structural form in which multiple extension portions intersect. The present application does not specifically limit the number of extension portions and the position relationship in each sub-pattern 32.

The embodiment of the present application provides a display screen cover plate 100, a third extension portion 36 is further arranged between the first extension portion 34 and the second extension portion 35, so that the third extension portion 36 is jointly enclosed to form a sub-opening 33 of the sub-pattern 32, and the sub-opening 33 has a larger opening area, thereby further improving the blocking range of the bubbles 1. The multiple extension portions can improve the limiting ability of the bubbles 1 and better restrict the bubbles 1 in the sub-opening 33.

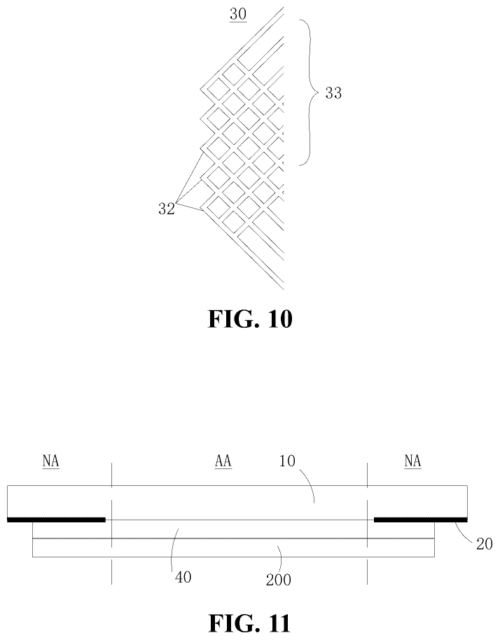

As an optional embodiment, referring to FIGS. 9 and 10. Adjacent parts of the sub-patterns 32 intersect with each other, and the sub-openings 33 of adjacent sub-patterns 32 partially overlap.

Optionally, multiple sub-patterns 32 may intersect with each other to form a cross structure, and there is a partial overlap between the sub-openings 33. The cross structure can block the movement and extension of the bubbles 1.

The intersection between the sub-patterns 32 may be arranged in a variety of combinations, and may form a regular cross structure or an irregular cross structure. The intersection point formed can be single or multiple, which can be determined according to the complexity of the actual required pattern. This application does not limit this.

The embodiment of the present application provides a display screen cover plate 100, which further improves the complexity of the first pattern 30 by intersecting adjacent sub-patterns 32, on the basis of using multiple sub-patterns 32 to block the bubbles 1 layer by layer, thereby forming a more sufficient restriction on the bubbles 1 and improving the blocking ability of the bubbles 1.

As an optional embodiment, referring to FIG. 10, multiple sub-patterns 32 intersect with each other so that the first pattern 30 forms a grid-shape structure, and mesh holes are formed at the overlapping positions of the sub-openings 33 of the multiple sub-patterns 32, and the opening portion 31 includes multiple mesh holes.

Optionally, multiple sub-patterns 32 can form a grid-shape structure on the basis of intersection, so that the opening portion 31 has multiple mesh holes, which can further form layers of resistance to the extension of the bubbles 1. The mesh holes can effectively limit some small bubbles 1, and the density of the mesh holes can be adjusted according to the actual resistance requirements.

The embodiment of the present application provides a display screen cover plate 100, by arranging the first pattern 30 as a grid-shape structure, the complexity of the first pattern 30 is further improved, and on the basis of improving the ability to block the bubbles 1, the first pattern 30 is also made more regular, which is conductive to the process molding of the first pattern 30.

As an optional embodiment, the mesh holes each includes a diamond hole structure.

The embodiment of the present application provides a display screen cover plate 100, herein the mesh holes are arranged as a diamond hole structure, which conforms to the extension direction of the bubbles 1 and increases the area of the mesh holes, thereby having a larger restriction range for the bubbles 1, and effectively preventing the bubbles 1 from extending from the border area NA to the visible area AA.

As an optional embodiment, the display screen cover plate 100 includes an optical adhesive layer 40, the optical adhesive layer 40 and the light shielding layer 20 are located on the same side of the substrate 10, part of the optical adhesive layer 40 is arranged on the side of the light shielding layer 20 away from the substrate 10 and filled in the concave-convex surface 21, and an orthographic projection of the optical adhesive layer 40 on the substrate 10 covers at least part of the concave-convex surface 21.

In this embodiment, the optical adhesive layer 40 is arranged at the bottoms of the substrate 10 and the light shielding layer 20, and the optical adhesive layer 40 is filled in the concave-convex surface 21 of the light shielding layer 20, so that the concave-convex surface 21 is used to form a layer-by-layer barrier for the bubbles 1 generated by the bending in the optical adhesive layer 40, thereby limiting the further extension of the bubbles 1.

Optionally, the optical adhesive layer 40 may be made of OCA material, and the display screen cover plate 100 may be directly bonded to the bottom display panel 200 through the optical adhesive layer 40.

The embodiment of the present application provides a display screen cover plate 100, an optical adhesive layer 40 is arranged at the bottom of the concave-convex surface 21 of the light shielding layer 20, the optical adhesive layer 40 can be directly used to be bonded with the display panel 200, the extension of the bending bubbles 1 can be effectively restricted by the concavo-convex surface 21.

As an optional embodiment, the orthographic projection of the optical adhesive layer 40 on the substrate 10 covers part of the concave-convex surface 21 and another part of the concave-convex surface 21 is arranged beyond the optical adhesive layer 40.

The embodiment of the present application provides a display screen cover plate 100, a portion of the concave-convex surface 21 is bonded with the optical adhesive layer 40 and the other portion of the concave-convex surface 21 is arranged beyond the optical adhesive layer 40, so that the concave-convex surface 21 is used to block the bubbles 1 from extending toward the visual area AA, and it is also conductive to discharging the bubbles 1 formed between the two through the outside of the concave-convex surface 21 during the bonding process of the two, thereby providing space for the discharge of excess bubbles 1, further reducing the probability of generating bubbles 1, and having better safety performance.

As an optional embodiment, the concave-convex surface 21 and the visible area AA are arranged at an interval, and a minimum distance from the concave-convex surface 21 to the visible area AA includes 0.1-0.2 mm.

The embodiment of the present application provides a display screen cover plate 100, the distance between the concave-convex surface 21 and the visible area AA is controlled within the above-mentioned range, while ensuring that the concave-convex surface 21 can be used to block the bending bubbles 1, it also ensures a safe distance between the concave-convex surface 21 and the visible area AA, preventing the concave-convex surface 21 from causing adverse effects on the electrical characteristics of the visible area AA, and providing reliable protection for the normal display of the visible area AA.

As an optional embodiment, the concave-convex surface 21 includes a groove, and a depth of the groove being half of a thickness of the light shielding layer 20.

The embodiment of the present application provides a display screen cover plate 100. The depth of the groove in the concave-convex surface 21 is controlled to be half of the overall thickness of the light shielding layer 20, the groove can be used to block the extension of the bubbles 1, and the light shielding layer 20 can be ensured not to be penetrated, so that the light shielding layer 20 has better structural strength, which reduces the risk of shedding due to insufficient structural strength, and improves the effectiveness of the light shielding layer 20.

Referring to FIG. 11. According to an embodiment of the present application, there is provided a display module, including the display screen cover plate 100 and the display panel 200 as described above. The display panel 200 and the light shielding layer 20 are located on the same side of the substrate 10. The display panel 200 includes a display area and a peripheral area, at least part of the peripheral area surrounds the display area arranged correspondingly to the visible area AA in a thickness direction of the display panel 200, the peripheral area being arranged correspondingly to the border area NA in the thickness direction, and the display area of the display panel 200 emitting light through the visible area AA.

According to an embodiment of the present application, there is provided a display device, including the display module as described above.

Optionally, the display device may be all products related to display, such as lighting, car lights, mobile phones, televisions, tablets, car displays, etc. The present application does not specifically limit the specific types of display devices.

The embodiment of the present application provides a display screen cover plate, a display module and a display device. A light shielding layer is provided at the border area of a substrate so that the bottom of the light shielding layer is provided with a concave-convex surface. When the bottom of the light shielding layer is bonded with an optical adhesive layer, even after multiple bending, bubbles in the optical adhesive layer may be blocked by the concave-convex surface of the light-shielding layer to alleviate the extension of the bubbles, thereby reducing the risk of shedding between film layers due to the extension of the bubbles, improving the overall reliability of the display module, and preventing the module failure problem caused by shedding between structures. Simultaneously, the concave-convex surface of the light shielding layer can also prevent bubbles from extending into the visible area, effectively limiting the bubbles to the border area, avoiding the blocking effect of bubbles on normal display, providing reliable guarantee for high-quality display, and ultimately improving the product yield with a more reliable display effect.

Although the present application has been described with reference to the preferred embodiments, various modifications may be performed thereto and equivalents may be substituted for parts thereof without departing from the scope of the present application. In particular, as long as there is no structural conflict, the various technical features mentioned in the various embodiments can be combined in any manner. The present application is not limited to the specific embodiments disclosed herein, but includes all technical solutions falling within the scope of the claims.

What is claimed is:

1. A display screen cover plate, comprising:
a substrate comprising a visible area and a border area, wherein the border area is arranged around the visible area; and
a light shielding layer arranged on one side of the substrate and located in the border area, wherein at least part of a surface of one side of the light shielding layer facing away from the substrate is a concave-convex surface, and an orthographic projection of the concave-convex surface on the substrate covers at least part of the border area.

2. The display screen cover plate according to claim 1, wherein the display screen cover plate comprises a bending area and a bending line located in the bending area and is capable of being bent with the bending line as an axis, and an end portion of the bending line is located within the orthographic projection of the concave-convex surface on the substrate.

3. The display screen cover plate according to claim 2, wherein the orthographic projection of the concave-convex surface on the substrate is symmetrically distributed with the bending line as the axis.

4. The display screen cover plate according to claim 1, wherein the concave-convex surface comprises a first pattern, an orthographic projection of the first pattern in a thickness direction of the substrate protruding and extending toward the visible area, and the first pattern has an opening portion formed by enclosing, an orthographic projection of the opening portion in the thickness direction being arranged away from an opening of the visible area.

5. The display screen cover plate according to claim 4, wherein the first pattern comprises a groove and/or a protrusion, the groove and/or the protrusion being integrally formed with the light shielding layer.

6. The display screen cover plate according to claim 4, wherein the first pattern comprises a plurality of sub-patterns, each of which encloses to form a sub-opening, an orthographic projection of the sub-opening in the thickness direction being arranged away from the opening of the visible area, and a plurality of the sub-openings together forming the opening portion.

7. The display screen cover plate according to claim 6, wherein at least part of the sub-openings formed by the adjacent sub-patterns overlap.

8. The display screen cover plate according to claim 7, wherein in a direction from the border area to the visible area, the plurality of sub-patterns are spaced apart from each other and sizes thereof gradually increase, and in any two adjacent sub-patterns, a sub-opening of the sub-pattern close to one side of the visible area covers a sub-opening of other sub-pattern.

9. The display screen cover plate according to claim 8, wherein the sub-pattern comprises an arc-shaped structure, the sub-opening is in a semicircular structure, and in the direction from the border area to the visible area, radial dimensions of the plurality of sub-patterns gradually increase.

10. The display screen cover plate according to claim 8, wherein the sub-patterns each comprises a first extension portion and a second extension portion arranged intersectingly, the first extension portion extending along a first direction and the second extension portion extending along a second direction, the first extension portion and the second extension portion enclosing to form a sub-opening, and in the direction from the border area to the visible area, lengths of the first extension portions and the second extension portions of the plurality of sub-patterns gradually increase.

11. The display screen cover plate according to claim 10, wherein the sub-pattern comprises a third extension portion connected between the first extension portion and the second extension portion, the third extension portion extending along a third direction intersecting with the first direction and the second direction in pairs, and the first extension portion, the second extension portion and the third extension portion jointly enclose to form a sub-opening.

12. The display screen cover plate according to claim 7, wherein adjacent parts of the sub-patterns intersect with each other, and the sub-openings of adjacent sub-patterns partially overlap.

13. The display screen cover plate according to claim 12, wherein the plurality of sub-patterns intersect with each other so that the first pattern forms a grid-shape structure, and mesh holes are formed at overlapping parts of the sub-openings of the plurality of sub-patterns, and the opening portion comprises a plurality of the mesh holes.

14. The display screen cover plate according to claim 13, wherein the mesh holes each comprises a diamond hole structure.

15. The display screen cover plate according to claim 1, wherein the display screen cover plate comprises an optical adhesive layer, the optical adhesive layer and the light shielding layer are located on a same side of the substrate, part of the optical adhesive layer is arranged on a side of the light shielding layer away from the substrate and filled in the concave-convex surface, and an orthographic projection of the optical adhesive layer on the substrate covers at least part of the concave-convex surface.

16. The display screen cover plate according to claim 15, wherein the orthographic projection of the optical adhesive layer on the substrate covers part of the concave-convex surface and another part of the concave-convex surface is arranged beyond the optical adhesive layer.

17. The display screen cover plate according to claim 1, wherein the concave-convex surface and the visible area are arranged at an interval, and a minimum distance from the concave-convex surface to the visible area includes 0.1-0.2 mm.

18. The display screen cover plate according to claim 1, wherein the concave-convex surface comprises a groove, a depth of the groove being half of a thickness of the light shielding layer.

19. A display module, comprising:
a display screen cover plate comprising: a substrate comprising a visible area and a border area, wherein the border area is arranged around the visible area; and a light shielding layer arranged on one side of the substrate and located in the border area, wherein at least part of a surface of one side of the light shielding layer facing away from the substrate is a concave-convex surface, and an orthographic projection of the concave-convex surface on the substrate covers at least part of the border area; and
a display panel located on a same side of the substrate as the light shielding layer, wherein the display panel comprises a display area and a peripheral area, at least part of the peripheral area surrounds the display area arranged correspondingly to the visible area in a thickness direction of the display panel, the peripheral area being arranged correspondingly to the border area in the thickness direction, and the display area of the display panel emitting light through the visible area.

20. A display device, comprising a display module comprising:
a display screen cover plate comprising: a substrate comprising a visible area and a border area, wherein the border area is arranged around the visible area; and a light shielding layer arranged on one side of the substrate and located in the border area, wherein at least part of a surface of one side of the light shielding layer facing away from the substrate is a concave-convex surface, and an orthographic projection of the concave-convex surface on the substrate covers at least part of the border area; and
a display panel located on a same side of the substrate as the light shielding layer, wherein the display panel comprises a display area and a peripheral area, at least part of the peripheral area surrounds the display area arranged correspondingly to the visible area in a thickness direction of the display panel, the peripheral area being arranged correspondingly to the border area in the thickness direction, and the display area of the display panel emitting light through the visible area.
